(19) United States
(12) Patent Application Publication
(10) Pub. No.: US 2018/0175947 A1
(43) Pub. Date: Jun. 21, 2018

(54) Radio Frequency Device and Corresponding Method

(71) Applicant: Infineon Technologies AG, Neubiberg (DE)

(72) Inventors: Marc Tiebout, Finkenstein (AT); Michele Caruso, Villach (AT); Daniele Dal Maistro, Villach (AT); Peter Thurner, Weissensee (AT)

(21) Appl. No.: 15/825,785

(22) Filed: Nov. 29, 2017

(30) Foreign Application Priority Data
Dec. 19, 2016 (DE) 102016124783.9

(51) Int. Cl. H04B 17/12; H03L 7/093; H03L 7/089; H03L 7/183; H03G 3/20; H01Q 3/36; H01Q 3/28; H01Q 3/26; H04B 17/13

(52) U.S. Cl. CPC H04B 17/12; H03L 7/093; H03L 7/0891; H03L 7/183; H04B 17/13; H01Q 3/36; H01Q 3/28; H01Q 3/267; H03G 3/20

(57) ABSTRACT

According to an embodiment, a radio frequency device includes a phase locked loop circuit, and an automatic gain control circuit, where an output of an automatic gain control circuit is coupled to a reference signal input of the phase locked loop circuit.

This application claims the benefit of German Application No. 102016124783.9, filed on Dec. 19, 2016, which application is hereby incorporated herein by reference in its entirety.

### TECHNICAL FIELD

The present application generally relates to radio frequency (RF) devices, systems and methods.

### BACKGROUND

Phased array transmit/receive systems are an example for RF systems desired for many application such as broadcasting, radar, space communication, weather research, optics, radio frequency (RF) identification systems and tactile feedback systems. Such systems may also be used for gesture sensing, communication backhauling and high speed routing in wireless gigabit (WiGig) or other consumer wireless systems.

A phased array system comprises an array of antennas in which relative phases and amplitudes of a plurality of signals transmitted over the antennas or received via the antennas may be adjusted. This adjustment may be performed in various pails of the systems and devices, for example RF, intermediate frequency (IF) or baseband (BB) parts, before or after analog-to-digital or digital-to-analog conversion etc. By proper adjustment, an effective radiation pattern of the array may be formed in a desired manner, which is also referred to as beamforming. This beamforming of the radiation pattern occurs due to constructive and/or destructive interference between the signals transmitted by each antenna of the array of antennas. Through adjustable phase and amplitude relationships, so-called beamsteering may be performed, i.e. the radiation pattern may be modified also during transmission. Reception may be done in a similar manner, thus providing a reception sensitive to a particular radiation pattern, for example to radiation from a particular direction.

One type of phased arrays is a dynamic phased array. In a dynamic phased array, each signal path providing a signal to an antenna incorporates an adjustable phase shifter, and these adjustable phase shifters may for example collectively be used to move a radiation beam. Moreover, the signal paths may comprise adjustable amplifiers, which provide further adjustment possibilities. Such adjustable phase shifters and/or amplifiers may exhibit variations in the behavior for example due to process variations or temperature variations. This influences the accuracy of a radiation pattern generated or received and/or may influence the accuracy of beamsteering. Generally, for exact beamsteering exact phase relationship between various signal paths are required.

Generating the signals to be transmitted, processing the signals to be received or calibration procedures for signal paths may involve the use of a local oscillator (LO) signal for example for signal synthesis (RFDAC), for up- or downconverting or for reference purposes. Generating such local oscillator signals often involves the use of a phase-locked loop (PLL).

As the phase relationships in such phase arrays are important, such PLLs should provide signals having stable phases as desired.

### SUMMARY

According to an embodiment, a radio frequency device includes a phase locked loop circuit, and an automatic gain control circuit, where an output of an automatic gain control circuit is coupled to a reference signal input of the phase locked loop circuit.

According to another embodiment, a method includes providing a reference signal, performing an automatic gain control on the reference signal to provide a gain control signal, providing the gain control signal to the phase locked loop at a reference input of the phase locked loop, and using an output of the phase locked loop in a radio frequency device.

The above summary is merely intended to give a brief overview of some embodiments and is not to be construed as limiting.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a block diagram of a radio frequency device according to an embodiment;

FIG. 2 is a diagram of a phased array system according to an embodiment;

FIG. 3 is a diagram of a phased array system according to an embodiment;

FIG. 4 is a block diagram of a phased-locked loop according to an embodiment;

FIG. 5 is a flow chart illustrating a method according to an embodiment;

FIGS. 6A to 6C are diagrams according to phased array systems according to some embodiments; and

FIG. 7 is a diagram of an automatic gain control circuit usable in some embodiments.

### DETAILED DESCRIPTION OF ILLUSTRATIVE EMBODIMENTS

In the following, various embodiments will be described in detail referring to the attached drawings. It should be noted that these embodiments are given by way of example only and are not to be construed as limiting. For example, while embodiments may be described comprising numerous features or elements, in other embodiments some of these features or elements may be omitted, and/or may be replaced by alternative features or elements. Also, apart from features or elements explicitly shown in the drawings or described herein, further features or elements, for example features or elements conventionally used in phased array systems, may be provided.

Features from different embodiments may be combined to form further embodiments unless noted otherwise. Variations or modifications described with respect to one of the embodiments may also be applicable to other embodiments.

In some of the embodiments a phased array device, for example an integrated chip to be used in a phased array system, may comprise a phase-locked loop. The phase-locked loop may be used to generate a local oscillator signal in some implementations. In embodiments, an automatic gain control (AGC) circuit is fed to keep an amplitude of a reference signal provided to the phase-locked loop constant. In some embodiments, this may improve a phase stability of an output signal of the PLL, as changes in amplitude of the reference signal may influence a phase of the output signal of the PLL.

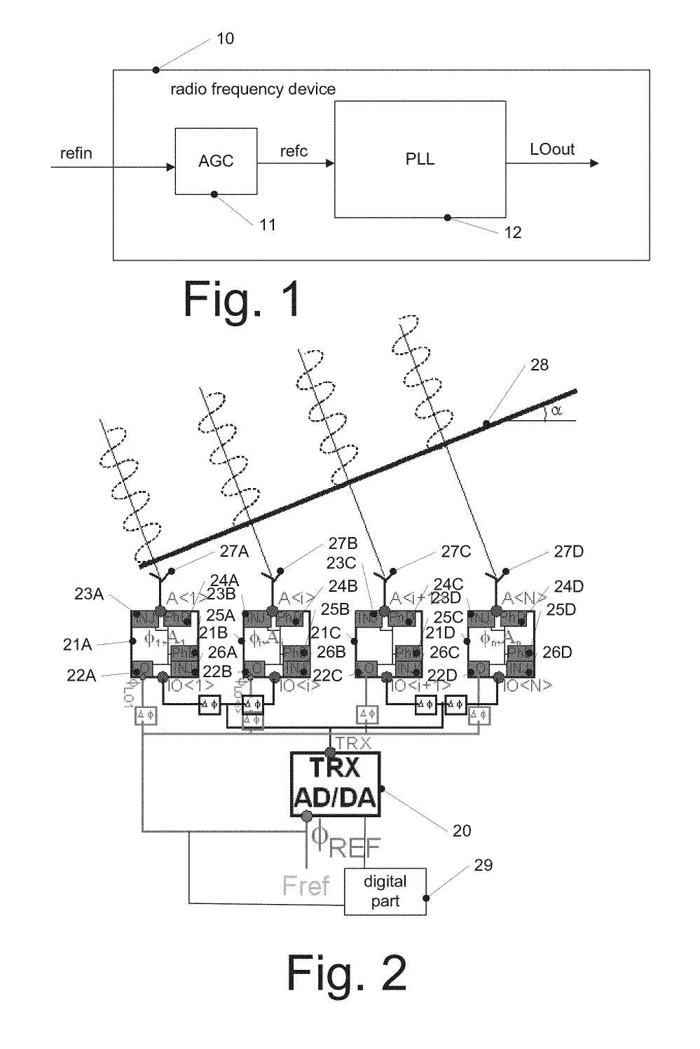

Turning now to the Figures, FIG. 1 is a block diagram illustrating some components of a radio frequency (RF) device 10 according to an embodiment. In some embodiments, radio frequency device 10 may be a phased array device, but is not limited thereto and may be any device where radio frequency signals are processed using for example a local oscillator (LO) signal, like RF transmitters or RF receivers.

RF circuit 10 in the embodiment of FIG. 1 comprises a phase-locked loop (PLL) circuit 12 to generate a local oscillator signal LOout. Local oscillator signal LOout may be used for example for mixing with an RF signal to generate an intermediate frequency (IF) signal or for calibration purposes as a reference signal or test signal in some embodiments. In some embodiments, signal LOout is employed in a phased array for reference or signal generation purposes. PLL circuit 12 may be realized in any conventional manner, for example as an integer N PLL circuit.

PLL circuit 12 is provided with a reference clock signal refc. In the embodiment of FIG. 1, refc is generated by an automatic gain control (AGC) circuit 11 based on a reference signal refin. Signal refin may be supplied to RF device 10 externally as shown, but may also be generated internally, for example by using an oscillator like a quartz crystal oscillator.

Automatic gain control circuit 11 may be implemented in any conventional manner used in the art for automatic gain control circuits and ensure a constant amplitude of reference signal refc even if the amplitude of signal refin varies. This eliminates or at least reduces phase variations of signal LOout due to amplitude variations of signal refc, which would be more pronounced in some implementations if signal refin were fed as a reference signal to PLL circuit 12 without automatic gain control circuit 11.

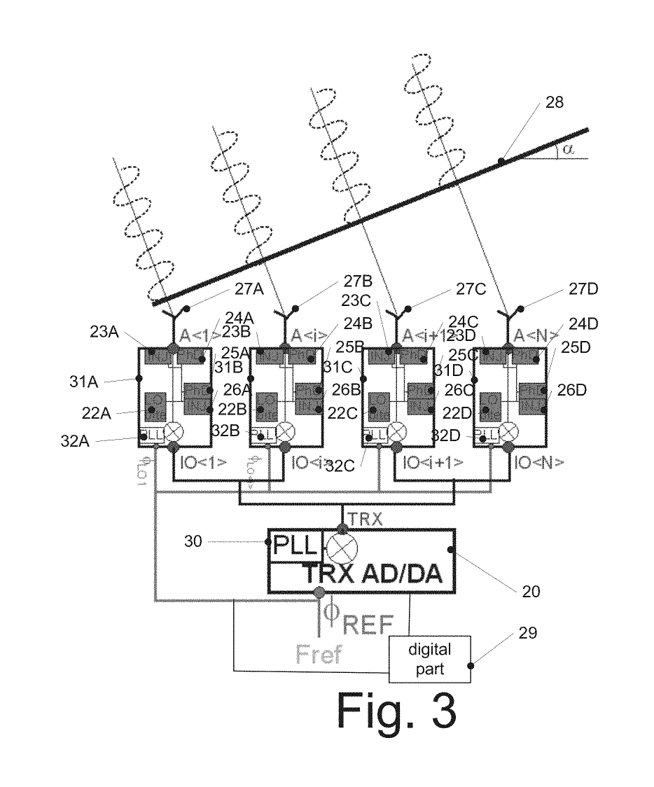

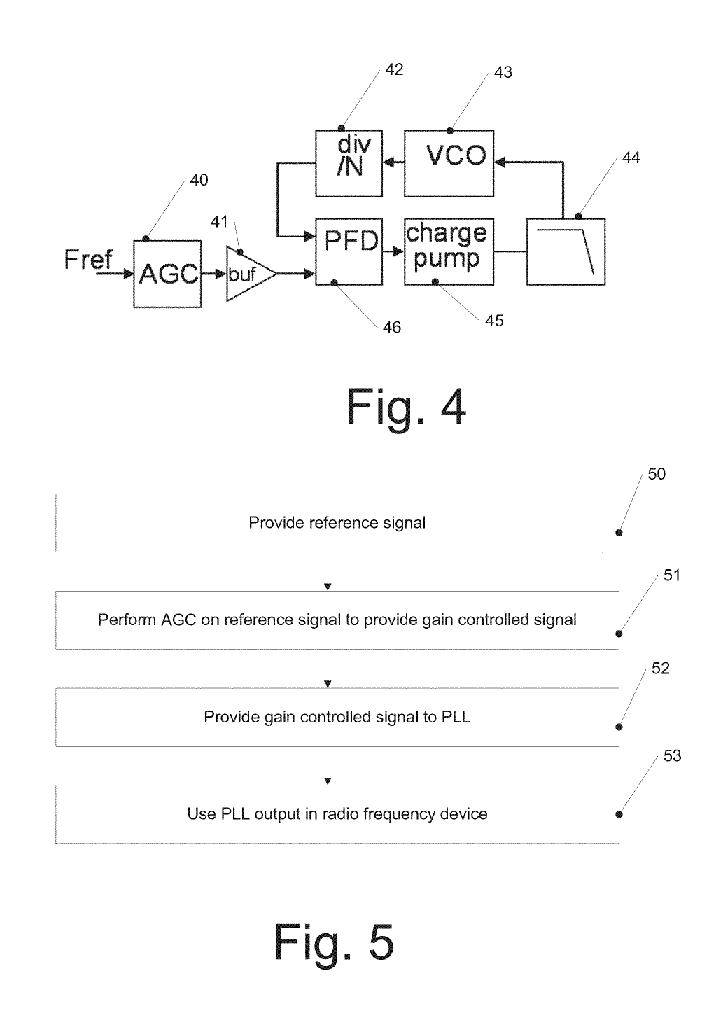

Next, an example environment where phase locked-loop circuits like phase locked loop circuit 12 a reference signal supplied to which is controlled by an automatic gain control circuit like automatic gain control circuit 11 of FIG. 1 may be used will now be described referring to FIGS. 2 and 3.

As non-limiting example environments, FIGS. 2 and 3 show phased array systems. In FIGS. 2 and 3, in order to avoid repetitions, corresponding or similar elements are denoted with the same reference numerals and will not be described twice. Furthermore, elements which occur in the systems a plurality of times are designated with the same number followed by a letter (A, B, . . .) and are collectively referred to by the number only (for example a reference to numeral 21 collectively refers to elements 21A, 21B . . . ).

In the phased array system of FIG. 2, for transmission a transmission/reception (TRX) analog-to-digital (AD)/ digital-to-analog (DA) converter 20 converts a digital representation of a signal to be transmitted received from a digital part 29, for example a digital signal processor (DSP), into an analog representation of the signal and transmits it to a plurality of phased array circuits 21, in the example of FIG. 2 four phased array circuits 21A to 21D. The number of four phased array circuits 21 in FIG. 2 is merely an example, and any number of phased array circuits 21 may be provided, for example up to several hundreds of such phased array circuits. In the example system of FIG. 2, each phased array circuit 21 controls a respective antenna 27. The analog transmit signal provided by TRX AD/DA 20 to each of phased array circuits 21 is adjusted with respect to phase φ and amplitude A in each of phased array circuits 21 versus the respective IO signal individually, such that signals with individually adjusted phases and amplitudes are transmitted by antennas 27. This is indicated by φ1 . . . φn and A1 . . . An in FIG. 2. Through constructive and destructive interference, this leads to beamforming. In the example of FIG. 2, a wavefront 28 forming an angle α to a direction defined by a plane in which antennas 27 are provided is formed. However, this is merely a non-limiting example. Phased array circuits 21 may further perform, when transmitting signals, a frequency upconversion to a radio frequency used for transmission.

When distributing the analog transmit signal from TRX AD/DA 20 to circuits 21, as indicated in FIG. 2 different phase offsets Δφ1 may occur due to different line length to circuits 21, which in embodiments are taken into account when adjusting the phase in circuits 21. Furthermore, phase offsets Δφ2 may occur when providing a reference signal Fref to circuits 21. Offset Δφ1, Δφ2 may be determined using techniques disclosed herein.

It should be noted that one or more circuits 21 may be integrated in a single chip, but may also be provided as separate chips. Often, in enlarged phased arrays having even some hundreds of antennas, a plurality of phased array chips are used, each serving a subset (i.e. one or more) of the antennas.

For receiving signals, signals received via antennas 27 are adjusted regarding amplitude and phase and possibly down converted to an intermediate frequency from a RF reception frequency. The thus adjusted signals are combined and provided to TRX AD/DA 20. Through constructive and destructive interference, the combination leads to a desired reception characteristic, for example a direction sensitive reception characteristic.

Furthermore, the phased array circuits 21 in the example of FIG. 2 each comprises built-in testing equipment (BITE) to measure and calibrate phase differences between the different phased array circuits 21. To this end, phased array circuits 21 comprise a first test signal injector 23, a second test signal injector 26, phase detectors 24, 25 and a local oscillator 22. Local oscillators 22 generate a local oscillator signal based on a signal as Ref supplied to all local oscillator circuits 22. Through different path lengths, phase differences Δφ may result in the signal Fref as provided to the local oscillator circuits 22. The components discussed above may be controlled by a digital interface (not explicitly shown in FIG. 2) to control local oscillator signal generation, signal injection and reading out phase/amplitude detectors 24, 25. Generally, for measuring relative phases, test signals are generated by injectors 23A, 26A and sent through the various signal paths, and phase/amplitude references measured by phase detectors 24, 25 which may be implemented for example as quadrature phase detectors. This calibration itself may be performed in any conventional manner and allows the calibration of the system illustrated in FIG. 2.

The local oscillator signal generated by local oscillator circuit 22 for such measurement may serve as a reference for phase detectors 24, 25. In addition, the local oscillator signal generated by local oscillators circuits 22 may also be used for other purposes in the circuit of FIG. 2, for example for up/downconversion. Local oscillator circuits 21 each may comprise a phase locked loop circuit to generate the PLL circuit, the signal Fref serving as a reference signal for the PLL. To avoid phase shifts of the local oscillator signals due to amplitude variations of Fref, a circuit as discussed in FIG. 1 may be employed with an automatic gain control regulating the amplitude of signal Fref to a desired constant value before providing it to the PLL circuits, as explained with reference to FIG. 1.

In the system of FIG. 2, local oscillator circuit 22 may be used to generate a local oscillator signal both for test reference purposes and possibly for other purposes in phased array circuits 21 like frequency up/downconversion. In other embodiments, separate phase locked loops are used. A corresponding system is shown in FIG. 3. To avoid repetitions, elements corresponding to elements already described with reference to FIG. 2 bear the same reference numeral and will not be described again in detail.

In the system of FIG. 3, a frequency required as intermediate frequency for up/downconversion differs from a frequency used for testing purposes. This may be the case for example in some fifth generation (5G) mobile phone/network systems which distribute signals at an intermediate frequency around 3 to 6 GHz instead of 28 GHz for fourth generation (4G) mobile phone/network systems. In this case, local oscillator circuits 22 are only used as reference for testing purposes. For up/downconversions, additional PLL circuits 32 are provided in phased array circuits 31, and an additional PLL is provided in TRX AD/DA 20. The additional PLLs 30, 32 are associated with mixers, as shown in FIG. 3. For all PLLs, both in local oscillator circuits 22 and for PLLs 32, variations of its absolute phase may disturb phase measurements for calibration purposes (in particular for local oscillator circuits 22) and the output phases of the signals transmitted via antennas (for PLLs 32, for example). Fixed time-invariant phase offsets may be compensated for by calibration, but changes made by changing amplitude of signal Fref cannot easily be compensated by such calibration. Therefore, in the system of FIG. 3 both PLLs in local oscillator circuits 22 and PLLs 30, 32 may be provided with an automatic gain control, as discussed with reference to FIG. 1, which reduces time variations of the output phase due to amplitude changes of Fref. Therefore, the use of AGC as discussed herein is not limited to a specific type or purpose of the PLL.

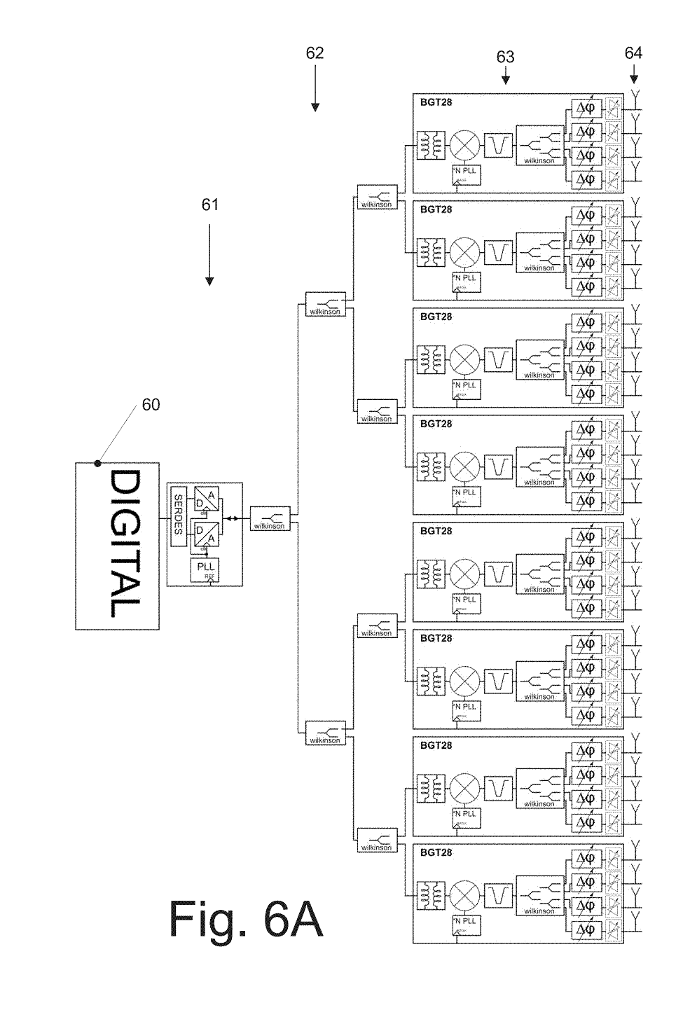

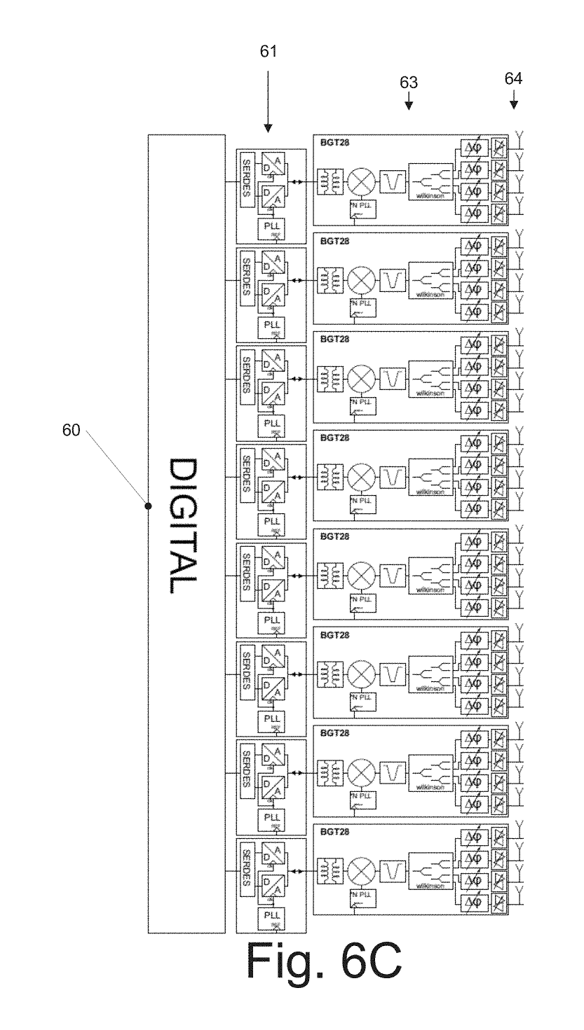

FIGS. 6A-6C show further examples for phased arrays with a plurality of PLLs used in AD/DA circuits or phased array circuits e.g. for up/downconversion. In FIGS. 6A-6C, a digital part 6o, for example a digital signal processor or other digital circuitry, provides a digital signal to one or more TRX AD/DA's 61 (for transmission) or receives a signal from them (for reception). TRX AD/DA's 61 each comprise a PLL as shown. The signal from the one or more TRX AD/DA's is provided to a plurality of phased array circuits 63 with associated antennas 64, which inter alia perform up/downconversion using a local oscillator signal generated by a PLL. Depending on the number of TRX AD/DA's 61 and phased array circuits 63, a distribution network, for example Wilkinson network, may be used to distribute the signal between TRX AD/DA's 61 and phased array circuits 63. The PLLs of FIGS. 6A to 6C may be provided with an AGC as discussed above or below with reference to FIG. 4. FIGS. 6A to 6C differ in the number of TRX AD/DA's used, illustrating that different topologies may be employed.

It should be noted that in other embodiments, only some of the PLLs of the system of FIGS. 2, 3 or 6A-6C may be provided with an automatic gain control.

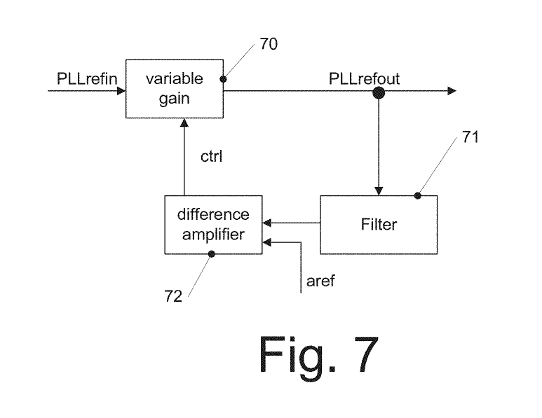

FIG. 4 illustrates a more detailed diagram of a PLL circuit usable in RF devices like the phased array systems of FIGS. 2 and 3 according to an embodiment. The PLL circuit of FIG. 4 receives a reference frequency signal Fref at an automatic gain control circuit 40. Automatic gain control circuit 40 outputs a signal based on signal Fref with an essentially constant amplitude. For example, the output voltage of AGC circuit 40 may regulate its output voltage to an internal reference voltage, provided for example by a bandgap circuit, or to an external reference voltage. In some embodiments, the amplitude (voltage) to which the reference signal Fref is regulated by AGC circuit 40 is selected based on a phase amplitude characteristic of the PLL circuit, by selecting a voltage where a sensitivity to the amplitude of the output phase to amplitude variations of Fref is lower than in other amplitude regions. For example, in some PLL implementations a sensitivity of an output phase to Fref amplitude variations may be higher for lower voltages than for higher voltages, and in such cases a comparatively higher voltage may be selected as an amplitude output by automatic gain control circuit 40. AGC circuit 40 may be implemented in any conventional manner known in the art for AGC circuits, e.g. by using a voltage reference like a bandgap reference or a signal derived therefrom, or any other sufficiently stable reference signal, as a reference amplitude for regulation. A simple non-limiting example for such an AGC circuit is shown in FIG. 7.

In the example of FIG. 7, a reference signal for a PLL PLLrefin (e.g. Fref of FIG. 4) is provided to a variable gain circuit 70 like a variable gain amplifier (VGA) or variable attenuation circuit for amplitude regulation to generate an amplitude controlled signal PLLrefout, which is then e.g. provided to a phase detector of a PLL loop as a reference signal. Furthermore, PLLrefout is provided to a filter 71, which may comprise a low pass filter, to generate a filtered signal essentially indicative of an amplitude of signal PLLrefout. The filtered signal is provided to a first input of a difference amplifier 72. An amplitude reference signal indicative of a desired amplitude, which may e.g. be derived from a bandgap reference or other stable voltage source, is provided to a second input of difference amplifier 72. Difference amplifier 72 outputs a control signal ctrl based on the difference between the filtered signal and signal aref to control variable gain circuit 70.

Returning to FIG. 4, the output signal of automatic gain control circuit 40 is provided to a buffer 41. An output signal of buffer 41 is provided to a first input of a phase frequency detector 46. An output of phase frequency detector 46 controls a charge pump 45 followed by a loop filter (low pass filter) 44. An output signal of loop filter 44 controls a voltage controlled oscillator (VCO) 43. An output signal of VCO 43 is used as an output of the PLL (for example as local oscillator signal in these systems of FIGS. 2 and 3) and is also provided to a frequency divider 42, which divides the frequency by an integer number N. An output of frequency divider 42 is provided to a second input of phase frequency detector 46. Elements 42 to 46 correspond to a conventional PLL implementation of an integer N PLL, and other conventional PLL implementations may also be used for receiving the reference signal provided by automatic gain control circuit 40 via buffer 41.

Furthermore, providing a reference signal with an automatic gain control may be applied both to analog and digital PLLs and is not limited in this respect.

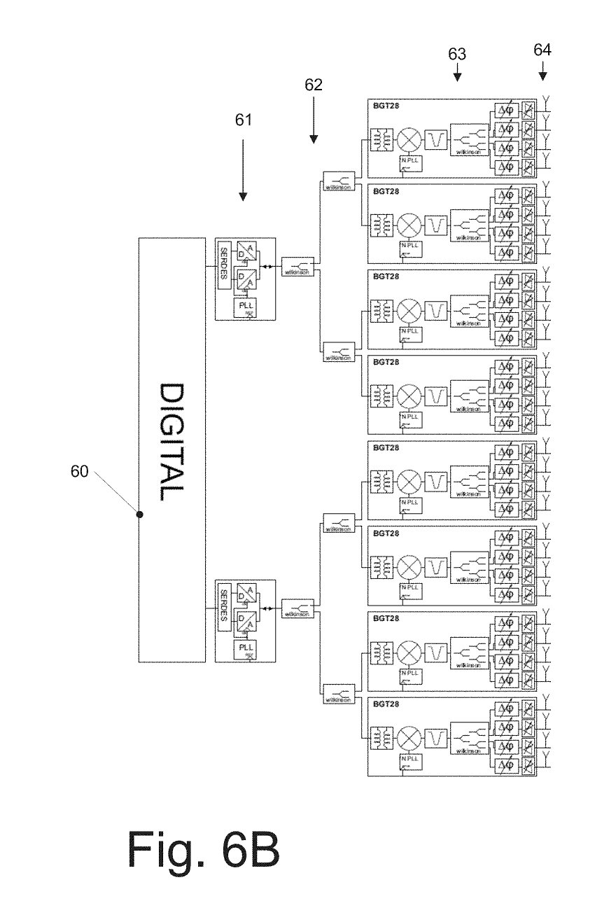

FIG. 5 is a flow chart illustrating a method according to an embodiment. The method of FIG. 5 may be implemented for example in the devices and systems illustrated referring to FIGS. 1-4, but is not limited thereto. Furthermore, while the method of FIG. 5 is shown and described as a series of acts or events, the order in which these acts or events are shown and described is not to be construed as limiting.

At 50 in FIG. 5, the method comprises providing a reference signal. At 51, the method comprises performing an automatic gain control on the reference signal to provide a gain controlled signal having a predetermined amplitude and/or a stable amplitude. “Stable amplitude” in this respect means that the amplitude is essentially stable over longer timescales, i.e. at least over a predetermined time depending on the requirements of an implementation, for example between calibrations of a system where the method is performed. It should also be noted that depending on the application, the absolute value of the amplitude needs not be at a precise value, but the amplitude only has to be sufficiently stable to prevent drifts and changes after the system has been calibrated. At 52, the method comprises providing the gain controlled signal to a phase locked loop circuit as a reference signal. At 53, an output signal of the phase locked loop is then used in a radio frequency (RF) circuit, for example in a phased array circuit or device for testing purposes like phase calibration, or for frequency conversion purposes in a mixer.

Details and variations described with respect to the devices and systems of FIGS. 1-4 may also be applicable to the method of FIG. 5.

The following embodiments are example embodiments.

Example 1. A radio frequency device (10), comprising: a phase locked loop circuit (12), and an automatic gain control circuit (11; 40), wherein an output of an automatic gain control circuit (11; 40) is coupled to a reference signal input of the phase locked loop circuit (12).

Example 2. The radio frequency device (10) of example 1, wherein the phase locked loop circuit (12) comprises an integer N phase locked loop circuit.

Example 3. The radio frequency device (10) of example 1, wherein the phase locked loop circuit (12) is configured to generate a local oscillator signal.

Example 4. The radio frequency device (10) of example 1, wherein the device further comprises test circuitry (22, 23, 24, 25, 26), wherein the test circuitry is coupled to an output of the phase locked loop circuit (12).

Example 5. The radio frequency device (10) of example 4, wherein the test circuitry (22, 23, 24, 25, 26) comprises at least one phase detector (24, 25) configured to use the output of the phase locked loop circuit as a reference.

Example 6. The radio frequency device (10) of example 1, wherein the automatic gain control circuit (11; 40)is configured to provide at least a predetermined stability of an amplitude of an output signal of the automatic gain control circuit (11; 40) over time.

Example 7. The radio frequency device (10) of example 1, further comprising a mixer coupled to an output of the phase locked loop circuit (12).

Example 8. The radio frequency device (10) of example 1, wherein the radio frequency device comprises a phased array device.

Example 9. The radio frequency device (10) of example 8, wherein the radio frequency device is configured to use an output signal of the phase locked loop (12) for phase calibration.

Example 10. A phased array system, comprising a plurality of radio frequency devices (10) of example 8, further comprising a reference signal line configured to provide a reference signal to the automatic gain control circuits of each of the devices.

Example 11. A method, comprising: providing a reference signal, performing an automatic gain control on the reference signal to provide a gain controlled signal, providing the gain controlled signal to the phase locked loop at a reference input of the phase locked loop, and using an output of the phase locked loop in a radio frequency device.

Example 12. The method of example 11, wherein using the output comprises using the output for calibration in a phased array system.

Example 13. The method of example 11, further comprising using the output for at least one of a frequency upconversion or a frequency downconversion.

Example 14. The method of example 12, wherein performing an automatic gain control comprising providing an amplitude of the gain controlled signal at least with a predetermined stability over time.

The above described embodiments are not to be construed as limiting the scope of the present application in any way.

What is claimed is:

1. A radio frequency device, comprising:
a phase locked loop circuit; and
an automatic gain control circuit, wherein an output of an automatic gain control circuit is coupled to a reference signal input of the phase locked loop circuit.

2. The radio frequency device of claim 1, wherein the automatic gain control circuit comprises:
a variable gain amplifier coupled between an input of the automatic gain control circuit and the output of the automatic gain control circuit;
a filter having an input coupled to the output of the automatic gain control circuit; and
a difference amplifier coupled between the output of the automatic gain control circuit and a control input of the variable gain amplifier.

3. The radio frequency device of claim 1, wherein the phase locked loop circuit comprises an integer N phase locked loop circuit.

4. The radio frequency device of claim 1, wherein the phase locked loop circuit is configured to generate a local oscillator signal.

5. The radio frequency device of claim 1, further comprising test circuitry, wherein the test circuitry is coupled to an output of the phase locked loop circuit.

6. The radio frequency device of claim 5, wherein the test circuitry comprises at least one phase detector configured to use the output of the phase locked loop circuit as a reference.

7. The radio frequency device of claim 1, wherein the automatic gain control circuit is configured to provide at least a predetermined stability of an amplitude of an output signal of the automatic gain control circuit over time.

8. The radio frequency device of claim 1, further comprising a mixer coupled to an output of the phase locked loop circuit.

9. The radio frequency device of claim 1, wherein the radio frequency device comprises a phased array device.

10. The radio frequency device of claim 9, wherein the radio frequency device is configured to use an output signal of the phase locked loop for phase calibration.

11. A phased array system, comprising a plurality of radio frequency devices of claim 9, and further comprising a reference signal line configured to provide a reference signal to the automatic gain control circuits of each of the devices.

12. A method, comprising:
providing a reference signal;
performing an automatic gain control on the reference signal to provide a gain controlled signal;
providing the gain controlled signal to a phase locked loop at a reference input of the phase locked loop; and
using an output of the phase locked loop in a radio frequency device.

13. The method of claim 12, wherein using the output comprises using the output for calibration in a phased array system.

14. The method of claim 13, wherein performing the automatic gain control comprises providing an amplitude of the gain controlled signal at least with a predetermined stability over time.

15. The method of claim 12, further comprising using the output for at least one of a frequency upconversion or a frequency downconversion.

16. A phased array radio frequency (RF) system comprising:
a plurality of phased array circuits, wherein each of the plurality of phased array circuits comprises
a plurality of front-end circuits configured to be coupled to corresponding antenna elements of a phased array antenna;
a mixer coupled to each of the front-end circuits;
a phase locked looped having an output coupled to a local oscillator input of the mixer; and
an automatic gain control circuit having a first output coupled to a reference input of the phase locked loop, wherein the automatic gain control circuit is configured to provide a constant amplitude at the first output.

17. The phased array RF system of claim 16, wherein each of the plurality of phased array circuits comprises a plurality of adjustable phase shifters, and each of the plurality of adjustable phase shifters coupled is between the mixer and corresponding ones of the plurality of front-end circuit.

18. The phased array RF system of claim 16, further comprising the phased array antenna.

19. The phased array RF system of claim 16, wherein the automatic gain control circuit comprises:
a variable gain amplifier coupled between an input of the automatic gain control circuit and the first output;
a filter having an input coupled to the first output; and
a difference amplifier coupled between an output of the filter and a control input of the variable gain amplifier.

20. The phased array RF system of claim 16, wherein each of the plurality of front-end circuits of the plurality of phased array circuits comprises a transceiver.
